(19) United States
(12) Patent Application Publication
(10) Pub. No.: US 2017/0140953 A1
(43) Pub. Date: May 18, 2017

(54) SYSTEMS AND METHODS FOR ION BEAM ETCHING

(71) Applicant: Hari Hegde, Fremont, CA (US)

(72) Inventor: Hari Hegde, Fremont, CA (US)

(73) Assignee: Plasma-Therm NES LLC, St. Petersburg, FL (US)

(21) Appl. No.: 12/244,683

(22) Filed: Oct. 2, 2008

(51) Int. Cl. H01L 21/306; C23F 1/08; B44C 1/22

(52) U.S. Cl. CPC H01L 21/67063

(57) ABSTRACT

An ion system for use in an etching system for etching at least a wafer using a gas. The ion system may include an ion chamber for containing charged particles generated from the gas. The ion system may also include a magnetic device surrounding at least a portion of the ion chamber. The magnetic device may affect the distribution of the charged particles in the ion chamber. The ion system may also include a grid assembly disposed between the ion chamber and the wafer when the wafer is etched. The charged particles may be provided through the grid assembly to etch the wafer when the wafer is etched.

### BACKGROUND OF THE INVENTION

Etching systems, such as ion beam etching systems, are employed in various industries for fabricating devices on wafers. The industries may include, for example, magnetic read/write and storage, optical system, semiconductor, and micro-electromechanical system (MEMS) industries.

A typical ion beam etching system may include an ion source unit (or ion system) for generating and providing ions. The ion bean etching system may also include a grid assembly disposed between the ion source unit and a wafer for forming a broad ion beam to etch the wafer. The ion beam may etch away unprotected/unwanted material from the wafer to form device structures. The ion density of the ion beam may be highest at the center of the ion beam and may reduce towards the edge of the ion beam, such that the ion density at the edge of the ion beam may be significantly lower than the ion density at the center of the ion beam. As a result, the etch rate near the edge of the wafer may be substantially lower than the etch rate at the center of the wafer, as illustrated in the example of FIG. 1.

FIG. 1 shows a schematic chart illustrating normalized etch rates corresponding to different radial positions on a wafer in utilizing an example conventional etching system. As illustrated in the example of FIG. 1, on the wafer, the etch rate at a radial position greater than 80 mm on the wafer may be lower than 80% of the etch rate at the center of the wafer. Etch rates are significantly reduced towards the edge of the wafer. The lack of etch rate uniformity may have significant negative effects on the yield of device fabrication, especially for wafers with large diameters, such as 8-inch wafers.

A prior-art technique to improve etch rate uniformity is to increase the sizes of holes of the grid assembly towards the edge of the grid assembly, for compensating the reduction of ion density near the edge of the wafer. For example, the holes corresponding to zone 2 of the wafer may be made larger than the holes corresponding the central zone 1 of the wafer, the grid assembly holes corresponding to zone 3 of the wafer may be made larger than the holes corresponding to zone 2 of the wafer, and so on, wherein the zones are illustrated in the example of FIG. 1.

However, when ion distribution varies significantly across the radius of the ion source (or ion system), grid zoning with large variation in the sizes of the holes may cause ion beam characteristics, such as divergence, to vary across the ion beam. As a result, etch uniformity and desired device feature uniformity may not be achieved. In addition, a substantial amount of the unwanted material that is etched away from the wafer may sputter and adhere to the grid assembly. The deposition of the unwanted material on the grid assembly may substantially alter the sizes of the holes, causing the sizes of the holes to deviate from the designed, desirable sizes. Additionally, thermal cycling of the source causes the grid assembly to be stressed and caused the grid flatness to deviate from the design point. As a result, etch rate uniformity may substantially deteriorate over time.

According to the prior-art technique, to maintain an acceptable yield, grid assemblies may need to be frequently replaced. The frequent replacement of the grid assemblies may undesirably incur material costs, labor costs, system down time, and waste of resource.

Another prior-art technique may involve providing an electromagnet disposed inside the ion source unit (or ion system) and near the gas inlet to generate a magnetic field for changing the density/distribution of the ions inside the ion source unit. The prior-art technique may not be able to adjust ion distribution in etching processes that require high ion-beam flux/current since the required high gas pressure may cause significant ion collision effects inside the ion source unit, especially near the ion outlet; as a result the magnetic field may not be able to effectively influence the ion distribution. The prior art technique may not be able to provide sufficient adjustment of the ion density distribution in response to the changes in the grid assembly caused by, for example, the deposition of the waste material etched away from the wafer.

### SUMMARY OF INVENTION

An embodiment of the present invention relates to an ion system for use in an etching system for etching at least a wafer using a gas. The ion system may include an ion chamber for containing charged particles generated from the gas. The ion system may also include a magnetic device surrounding at least a portion of the ion chamber. The magnetic device may affect the distribution of the charged particles in the ion chamber. The ion system may also include a grid assembly disposed between the ion chamber and the wafer when the wafer is etched. The charged particles may be provided through the grid assembly to etch the wafer when the wafer is etched.

The above summary relates to only one of the many embodiments of the invention disclosed herein and is not intended to limit the scope of the invention, which is set forth is the claims herein. These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a schematic chart illustrating example normalized etch rates corresponding to different radial positions on a wafer in an example conventional etching system.

FIG. 2A shows a schematic representation illustrating an etching system in accordance with one or more embodiments of the present invention.

FIG. 2B shows a schematic representation illustrating a gas distribution system in the etching system illustrated in the example of FIG. 2A in accordance with one or more embodiments of the present invention.

FIG. 2C shows a schematic representation illustrating a cut-away view of an ion system in the etching system illustrated in the example of FIG. 2A in accordance with one or more embodiments of the present invention.

FIG. 3 shows a schematic representation illustrating an ion system for use in an etching system in accordance with one or more embodiments of the present invention.

FIG. 4 shows a schematic representation illustrating an ion system for use in an etching system in accordance with one or more embodiments of the present invention.

FIG. 5 shows a schematic chart illustrating example magnetic field strength values corresponding to different radial positions in an ion chamber for use in an etching system in accordance with one or more embodiments of the present invention.

FIG. 6A shows a schematic representation illustrating a grid assembly for use in an etching system in accordance with one or more embodiments of the present invention.

FIG. 6B shows a schematic representation illustrating a cut-away view of the grid assembly illustrated in the example of FIG. 6A in accordance with one or more embodiments of the present invention.

FIG. 6C shows a schematic representation illustrating a partial cross-sectional view of the grid assembly illustrated in the example of FIG. 6A in accordance with one or more embodiments of the present invention.

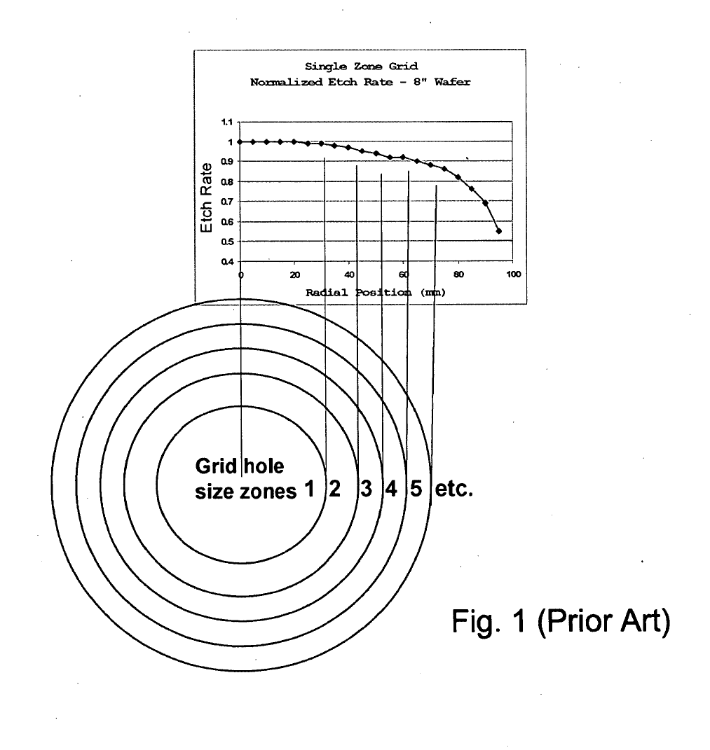

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

One or more embodiments of the invention relate to an ion system for use in an etching system for etching at least a wafer using a gas. The ion system may include an ion chamber for containing charged particles (or ions) generated from the gas. The charged particles may be generated when the gas is excited by a set of radio frequency coils, which may surround at least a portion of the ion chamber.

The ion system may also include at least a magnetic device surrounding at least a portion of the ion chamber. The position of the magnetic device relative to the ion chamber and/or the magnetic field provided by the magnetic device may be controlled for optimizing the ion distribution, thereby achieving and maintaining desirable ion beam uniformity in etching the wafer. For example, the magnetic device may be positioned near the ion outlet of the ion system. Accordingly, not only applicable for optimizing etch uniformity in relatively low-ion-beam-current etching processes, the magnetic device may also affect the distribution of the charged particles even in relatively high-pressure regimes in the ion chamber, for optimizing etch uniformity in relatively high-ion-beam-current etching processes. As another example, the magnetic device may be positioned about midway of the ion chamber or near the gas inlet to affect ion distribution to satisfy different etching process requirements.

Alternative or in addition to the magnetic device, the ion system may include a multi-zone gas input mechanism for supplying the gas into the ion chamber. For example, the ion system may include a first set of gas channels and a second set of gas channels, wherein the first set of gas channels may provide a first portion of the gas into the ion chamber at a first flow rate, and the second set of gas channels may provide a second portion of the gas into the ion chamber at a second flow rate that is different from the first flow rate. As an example, the first set of gas channels may correspond to a central zone of the wafer; the second set of gas channels may surround the first set of gas channels and may correspond to an outer zone of the wafer. The second flow rate may be adjusted higher than the first flow rate for optimizing the uniformity of ion distribution at least in relatively low-pressure regimes in the ion chamber, thereby optimizing etching uniformity in relatively low-ion-beam-current etching processes. The flow rates may be separately or independently adjusted for optimizing the ion distribution, thereby optimizing the ion beam uniformity in etching the wafer.

Compared with prior-art systems, embodiments of the invention may provide more controllability for tuning ion distribution in high-pressure regimes, intermediate-pressure regimes, and low-pressure regimes in an ion source, to optimizing etching uniformity in various etching processes that may require various levels of ion beam current/flux. Etch uniformity may also be more easily achieved and maintained with embodiments of the invention.

Including the adjustable magnetic device and/or the multi-zone gas input mechanism, embodiments of the invention may optimize etch uniformity without the need of varying hole sizes across a grid assembly. The embodiments of the present invention may be deployed in conjunction with grid hole variations to obtain the best possible beam uniformity and device feature uniformity. Advantageously, costs and system down time associated with the grid assembly may be substantially reduced. Additionally, compared with etch uniformity provided by prior-art techniques, the etch uniformity provided by embodiments of the invention may be less sensitive to changes to the grid assembly caused by, for example, deposition of waste material sputtered on the grid assembly.

One or more embodiments of the invention relate to an etching system. The etching system may include an ion system having one or more features discussed above.

The etching system may also include a wafer support mechanism disposed in a processing chamber for supporting the wafer. The wafer support mechanism may be adjustable for optimizing the position and/or the orientation of the wafer with respect to the ion system and/or the ions (i.e., the charged particles) provided by the ion system.

The etching system or the ion system may also include a grid assembly for supplying the ions from the ion system to the processing chamber for etching the wafer. The grid assembly may include two or more grid members, such as two, three, or four grid members.

In one or more embodiments, the grid assembly may include a first grid member, a second grid member, and a third grid member, each including a set of holes for providing ions to etch the wafer. When the grid assembly is employed in etching the wafer, the first grid member may be electrically grounded, the second grid member may be electrically negative relative to the first grid member, and the third grid member may be electrically positive relative to the first grid member.

Among the three grid members, the first grid member (e.g., the ground grid member) may be disposed closest to the wafer during etching the wafer. The second grid member (e.g., the negative grid member) may be disposed between the first grid member and the third grid member (e.g., the positive grid member), with a first space existing between the first grid member and the second grid member, and with a second space existing between the second grid member and the third grid member. The second space may be larger than the first space for achieving desirable etch uniformity in etching the wafer. The first space may be relatively small for maintaining a desirable beam divergence and ion interception while etching the wafer.

In one or more embodiments, ion beam current at each grid hole may be inversely proportional to the square of the distance between two grid members. The second space (e.g., the space between the negative grid member and the positive grid member) may be configured relatively large such that small variations in the second space, for example, caused by warping of the grid assembly and/or deposition of sputtered waste material, may not cause significant ion beam current variation. As a result, ion beam uniformity may be substantially maintained, and the desirable etch uniformity may be achieved. The first space (e.g., the space between the ground grid member and the negative grid member) may be configured relatively small such that a sufficiently good beam collimation is maintained while keeping the grid intercept current sufficiently low. The relatively small first space may also help maintain the structural robustness/rigidity of the grid assembly.

The first grid member (e.g., the ground grid member), which faces the wafer during the etching, may be subjected to more sputtered material than the other two grid members. In one or more embodiments, the first grid member may be made thicker than one or more of the other two grid members. The thicker first grid member may strengthen the structural robustness/rigidity of the grid assembly against potential warping, thereby advantageously helping maintain ion beam uniformity for achieving a satisfactory fabrication yield. The thickness of the first grid member may also improve durability of the first grid member, thereby lengthening the life of the grid assembly.

Being at least partially shielded by the first grid assembly against the sputtered waste material, the second grid member (e.g., the negative grid member) and the third grid member (e.g., the positive grid member) may be made relatively thin compared with the first grid. Being thinner, the second grid member and the third grid member may avoid releasing too much material that may contaminate the wafer when the grid members are subjected to grid-hole etching by ions. The thinner second grid member and third grid member may also help preserve sufficient sizes of the second space and the first space, thereby advantageously maintaining the ion beam uniformity.

One or more embodiments of the invention relate to a method for etching a wafer. The method may include employing an ion chamber for containing charged particles, wherein the charged particles are to be utilized for etching the wafer. The method may also include surrounding the ion chamber with a magnetic device for affecting the distribution of the charged particles in the ion chamber. The method may also include moving the magnetic device with respect to the ion chamber for adjusting the distribution of the charged particles in the ion chamber. Accordingly, the uniformity of the charged particles supplied from the ion chamber may be optimized. Advantageously, the etch uniformity in etching the wafer may be optimized, and the production yield in fabricating devices on the wafer may be substantially improved.

The features and advantages of the present invention may be better understood with reference to the figures and discussions that follow.

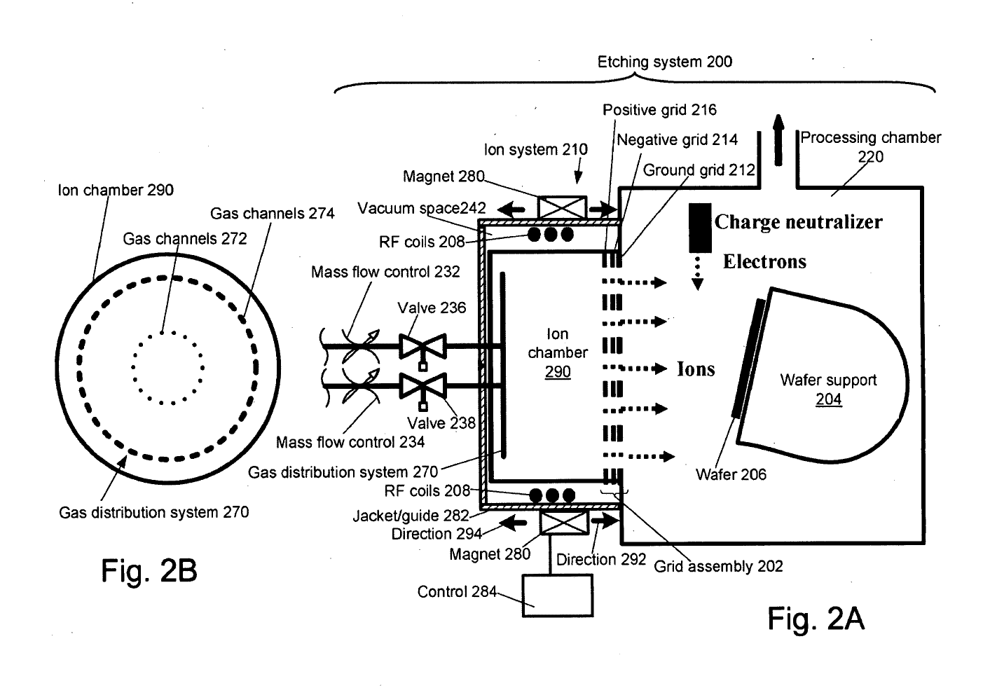

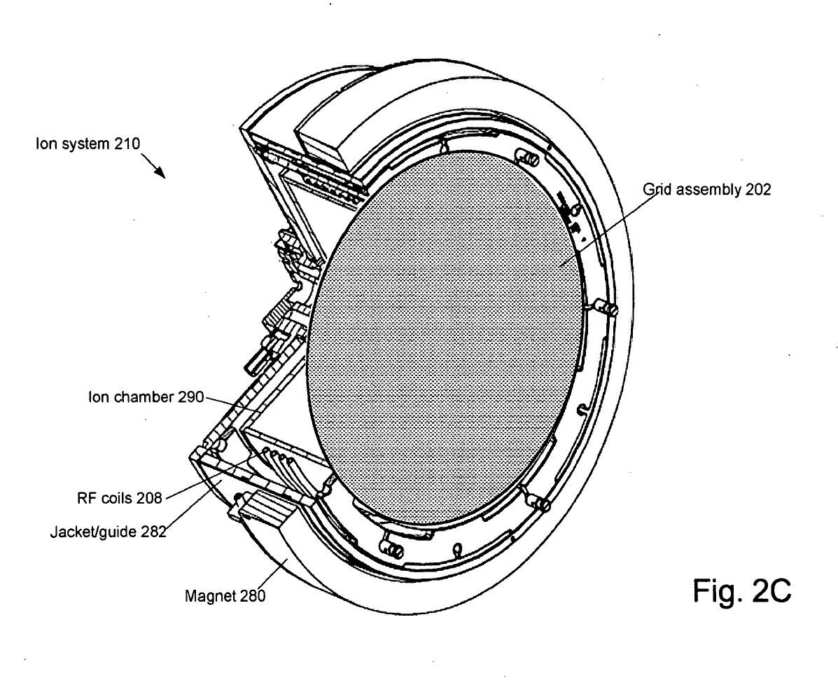

FIG. 2A shows a schematic representation illustrating an etching system 200 in accordance with one or more embodiments of the present invention. Etching system 200 may be utilized for etching wafers, such as a wafer 206, to fabricate devices. Etching system 200 may include a processing chamber 220, an ion system 210 coupled with processing system 220, and a wafer support mechanism 204 disposed inside processing chamber 220. As illustrated in the example of FIG. 2A, ion system 210 may provide ions (or charged particles) into processing chamber 220 for etching wafer 206, wherein wafer 206 may be supported by wafer support mechanism 204 inside processing chamber 220.

Ion system 210 may include an ion chamber 290, a gas distribution system 270 coupled with ion chamber 290, and a set of radio frequency coils 208 (or RF coils 208) surrounding at least a portion of ion chamber 290. Gas distribution system 270 may supply a gas into ion chamber 290. The gas may be excited by RF coils 208 to generate the charged particles that are provided into processing chamber 220 for etching wafer 206.

Ion system 210 may also include one or more mechanisms with novel and inventive features for improving etch uniformity in etching wafer 206. For example, ion system 210 may include an adjustable magnetic device 280 and associated control mechanisms, a multi-zone design of gas distribution system 270 and associated control mechanisms, and/or an optimal-spaced grid assembly 202, each having inventive features discussed below.

Magnetic device 280 may surround at least a portion of ion chamber 290 for affecting the distribution of the charged particles in ion chamber 290. A control device 284 may be coupled with magnetic device 280 for controlling magnetic device 280. For example, control device 284 may include a movement mechanism for actuating and controlling magnetic device 280 to move along and/or with respect to ion chamber 290 in at least one of direction 292 and direction 294. The inner diameter of magnetic device 280 may be larger than the outer diameter of RF coils 208, such that RF coils 208 may not interfere with the movement of magnetic device 280. Through the movement of magnetic device 280, the distribution of the charged particles may be tuned for optimizing the uniformity of ion beam provided into processing chamber 220.

As an example, magnetic device 280 may be concentric with ion chamber 290 and may be moved towards grid assembly 202 such that the distance between magnetic device 280 and grid assembly 202 (or a positive grid member 216 thereof) is less than the mean free path of the gas in ion chamber 290. With an azimuthally uniform magnetic field deployed close to grid assembly 202, ion distribution may still be tuned amid the significant ion collision effects in higher-pressure regimes inside ion chamber 290, and the density of ions may be increased towards the cylindrical wall of ion chamber 290. Advantageously, the ion beam uniformity may be improved not only in low-ion-beam-current etching processes, but also in intermediate-ion-beam-current etching processes and high-ion-beam-current etching processes.

In one or more embodiments, magnetic device 280 may represent an electromagnetic device, and control device 284 and/or another control unit of ion system 210 may include a current control device for controlling the amount and/or the distribution of electric current supplied to magnetic device 280 to tune the magnetic field provided by magnetic device 280 from near the cylindrical wall of ion chamber 290 to the center of ion chamber 290, thereby further tuning the ion beam uniformity.

Ion system 210 may also include a jacket 282, at least partially surrounded by magnetic device 280, for guiding the translation/movement of magnetic device 280 with respect to at least ion chamber 290. Jacket 282 may at least partially enclose ion chamber 290 to form a space 242 between jacket 282 and ion chamber 290. Space 242 may represent a vacuum space in one or more embodiments. RF coils 208 may be disposed in vacuum space 242, such that potential interference with the movement of magnetic device 280 may be prevented. Jacket 282 may be made of stainless steel. Being disposed external to jacket 282, magnetic device 280 may be cooled by ambient air.

Alternative or in addition to jacket 282, a jacket may enclose magnetic device 280 for protecting magnetic device 280. In fact, the magnetic device may be placed inside the vacuum, but avoiding interference with the RF coils 208. In one or more embodiments, magnetic device 280 may be cooled by water.

For improving etch uniformity, gas distribution system 270 may be implemented with a multi-zone gas input mechanism, as an alternative or additional mechanism for optimizing the etch uniformity. For example, gas distribution system 270 may include different gas channels for providing different portions of the gas at different flow rates, as discussed with reference to the example of FIG. 2B.

FIG. 2B shows a schematic representation illustrating gas distribution system 270 in accordance with one or more embodiments of the present invention. As an example, a first set of gas channels 272 of gas distribution system 270 may correspond to a central zone of wafer 206; a second set of gas channels 274 of gas distribution system 270 may surround first set of gas channels 272 and may correspond to an outer zone of wafer 206. The flow rate associated with first set of gas channels 272 (or the first flow rate) may be configured higher than the flow rate associated with second set of gas channels 274 (or the second flow rate), for improving uniformity of ion distribution at least in relatively low-pressure regimes in ion chamber 290, for optimizing etch uniformity at least in relatively low-ion-beam-current applications. In one or more embodiments, the opening size of each channel of first set of gas channels 272 may be smaller than the opening size of each channel of second set of gas channels 274, for reducing ion density near the central zone relative to the outer zone. Alternatively or additionally, the channel distribution density (i.e., number of channels per unit area) of first set of gas channels 272 may be different from (for example, lower than) the channel distribution density of second set of gas channels 274, for optimizing the distribution of ions.

The first flow rate and the second flow rate may be separately or independently adjusted for providing fine-tuning in optimizing the ion distribution, thereby optimizing the ion beam uniformity in etching wafer 206. For example, referring back to the example of FIG. 2A, ion system 210 may include a mass flow control 232 and a valve 236 for controlling the first flow rate, and a mass flow control 234 and a valve 238 for controlling the second flow rate. Accordingly, radial ion distribution in ion chamber 290 may be fine-tuned to achieve the optimal ion beam uniformity.

Referring to the example of FIG. 2A, in addition or alternative to magnet device 280 and/or gas distribution system 270, grid assembly 202 may be implemented with optimal spacing for optimizing the etch uniformity. Grid assembly 202 may include a first grid member 212 (or ground grid member 212), a second grid member 214 (or negative grid member 214), and a third grid member 216 (or positive grid member 216), each including a set of holes for enable ions to pass through to form an ion beam. When grid assembly 202 is employed in etching wafer 206, ground grid member 212 may be electrically grounded, negative grid member 214 may be electrically negative relative to ground grid member 212, and positive grid member 216 may be electrically positive relative to the ground grid member 212.

Among the three grid members, ground grid member 212 may be disposed closest to wafer 206 during etching wafer 206. Negative grid member 214 may be disposed between ground grid member 212 and positive grid member 216, with a first space existing between ground grid member 212 and negative grid member 214, and with a second space existing between negative grid member 214 and positive grid member 216. The second space may be larger than the first space for achieving desirable etch uniformity in etching wafer 206. The first space may be relatively small for maintaining a desirable beam divergence while etching wafer 206.

In one or more embodiments, ion beam current at each grid hole may be inversely proportional to the square of the distance between two grid members. The second space (e.g., the space between negative grid member 214 and positive grid member 216) may be configured relatively large such that small variations in the second space, for example, caused by warping of grid assembly 202 and/or deposition of sputtered waste material, may not cause significant ion beam current variation. As a result, ion beam uniformity may be substantially maintained, and the desirable etch uniformity may be achieved. The first space (e.g., the space between ground grid member 212 and negative grid member 214) may be configured relatively small such that a sufficiently good beam collimation and low enough ion intercept current into grids is maintained. The relatively small first space may also help maintain the structural robustness/rigidity of grid assembly 202.

Ground grid member 212, which faces wafer 206 during the etching, may be subjected to more sputtered material than the other two grid members. In one or more embodiments, ground grid member 212 may be made thicker than one or more of the other two grid members. The thicker ground grid member 212 may strengthen the structural robustness/rigidity of grid assembly 202 against potential warping, thereby advantageously helping maintain ion beam uniformity for achieving a satisfactory fabrication yield. The thickness of ground grid member 212 may also improve durability of ground grid member 212, thereby lengthening the life of grid assembly 202.

Being at least partially shielded by the first grid assembly against the sputtered waste material, negative grid member 214 and positive grid member 216 may be made relatively thin compared with the first grid. Being thinner, negative grid member 214 and positive grid member 216 may avoid releasing too much material that may contaminate wafer 206 when the grid members are subjected to grid-hole etching by ions. The thinner negative grid member 214 and positive grid member 216 may also help preserve sufficient sizes of the second space and the first space, thereby advantageously maintaining the ion beam uniformity and divergence characteristics.

Through the use of one or more of magnetic device 280, gas distribution system 270, and grid assembly 202, etch uniformity may be optimized, and the yield in fabricating devices may be improved. In one or more embodiments, with the optimal ion distribution provided by utilizing magnetic device 280 and/or gas distribution system 270, there may be no need to vary the sizes of the grid holes of grid assembly 202. Grid assembly 202 may be made with a uniform grid hole size. Alternatively, the hole size variations can be kept at a minimum. Advantageously, grid assembly 202 may be associated with lower costs, reduced system down time, and reduced sensitivity to deposition of sputtered waste material compared with prior art grid assemblies.

FIG. 2C shows a schematic representation illustrating a cut-away view of ion system 210 in etching system 200 illustrated in the example of FIG. 2A in accordance with one or more embodiments of the present invention. As illustrated in the example of FIG. 2C, RF coils 208 may surround at least a portion of ion chamber 290, for exciting gas inside ion chamber 290 to generate charged particles (or ions). Jacket 282 may enclose RF coils 208 to protect RF coil 208 and to prevent RF coils 208 from interfering with the movement of magnetic device 280. Magnetic device 280 may surround at least a portion of ion chamber 290 for affecting the distribution of the charged particles for achieving desirable ion uniformity. Magnetic device 280 may be disposed around jacket 282 and may be disposed external to jacket 282 and RF coils 208, such that the movement of magnetic device may be guided by jacket 282 and may not be hindered by RF coils 208. Magnetic device 280 may be moved with respect to grid assembly 202 to satisfy various manufacturing requirements. For example, magnetic device 280 may be moved towards grid assembly 202 for tuning the distribution of the charged particles in relatively high-ion-beam-current etching processes.

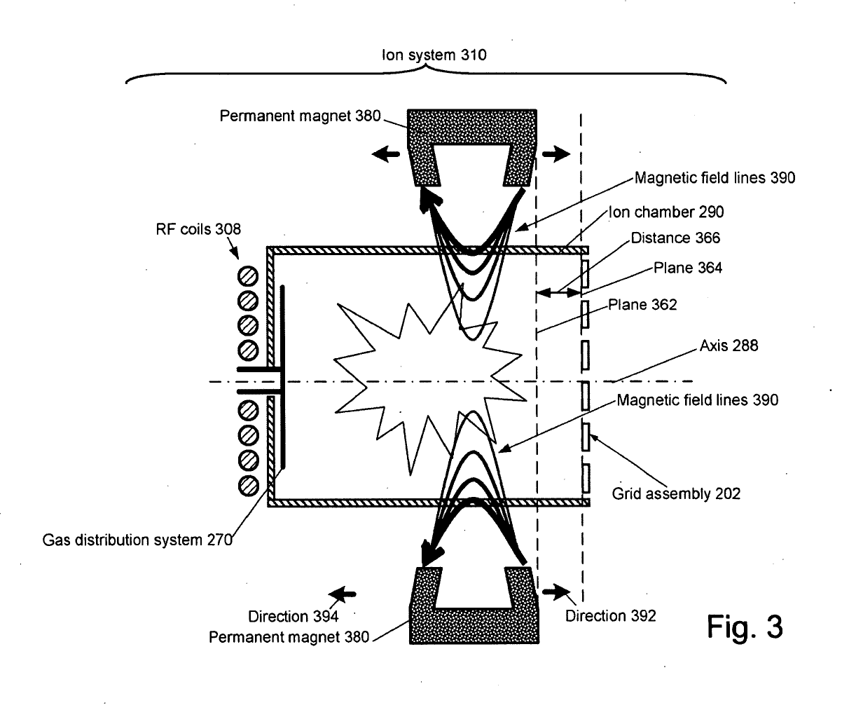

FIG. 3 shows a schematic representation illustrating a cross-sectional view of an ion system 310 for use in an etching system in accordance with one or more embodiments of the present invention. Ion system 310 may include one or more of ion chamber 290, grid assembly 202, and gas distribution system 270 discussed in the example of FIG. 2A.

Ion system 310 may also include a set of pancake-type radio frequency coils 308 (RF coils 308) which may surround the gas inlet of gas distribution system 270 and/or may be disposed at an end of ion chamber 290 that is opposite to grid assembly 202. RF coils 308 may excite the gas supplied by gas distribution system 270 to generate charged particles (or ions).

Ion system 310 may also include a permanent magnet 380 surrounding at least a portion of ion chamber 290. In one or more embodiments, permanent magnet 380 may include one or more of an NdFeB-type high strength magnet, or a SmCo-type high-strength magnet, or a traditional AlNiCo type magnet.

Permanent magnet 380 may provide a circularly uniform, symmetric magnetic field inside ion chamber 290 with a significant radial gradient of the magnetic field; the magnetic field may be represented by magnetic field lines 390. As illustrated by magnetic field lines 390, the circularly uniform magnetic field may be symmetric with respect to the central axis 288 of ion chamber 290, in contrast with asymmetric cusp magnetic field patterns that may be found in existing magnetic field applications. Cusp magnetic fields may reduce ion beam uniformity.

The density of magnetic field lines 390 may decrease from permanent magnet 380 towards the central axis 288 of ion chamber 290. Accordingly, permanent magnet 380 may be utilized for tuning the ion distribution in ion chamber 290, e.g., increasing ion density towards the cylindrical wall of ion chamber 290, thereby optimizing the etch uniformity when utilizing the etching system in etching a wafer. Permanent magnet 380 may be moved in at least one of direction 392 and direction 394 with respect to grid member 202 to providing further tuning.

In one or more embodiments, permanent magnet 380 may be disposed near grid assembly 202. For example, distance 366 between plane 362 of permanent magnet 380 and plane 364 of grid assembly 202 may be no more than the mean free path of the gas in ion chamber 290. Plane 362 may represent an imaginary plane that is perpendicular to central axis 288 and contains surface(s) of permanent magnet 380 that are closest to grid assembly 202. Plane 364 may represent an imaginary plane that is perpendicular to central axis 288 and contains surface(s) of grid assembly 202 that are closest to permanent magnet 380. Accordingly, permanent magnet 380 may be utilized in tuning the ion distribution in at least an etching process that may require relatively high ion-beam current/flux. In addition or alternative to permanent magnet 380, gas distribution system 270 and associated control mechanisms may be utilized in tuning the ion distribution in at least an etching process that may require relatively low ion-beam current/flux. In one or more embodiments, both permanent magnet 380 and gas distribution system 270 may be utilized in an etching process that may require intermediate ion-beam current/flux. Advantageously, comprehensive controllability for optimizing the etch rate may be provided.

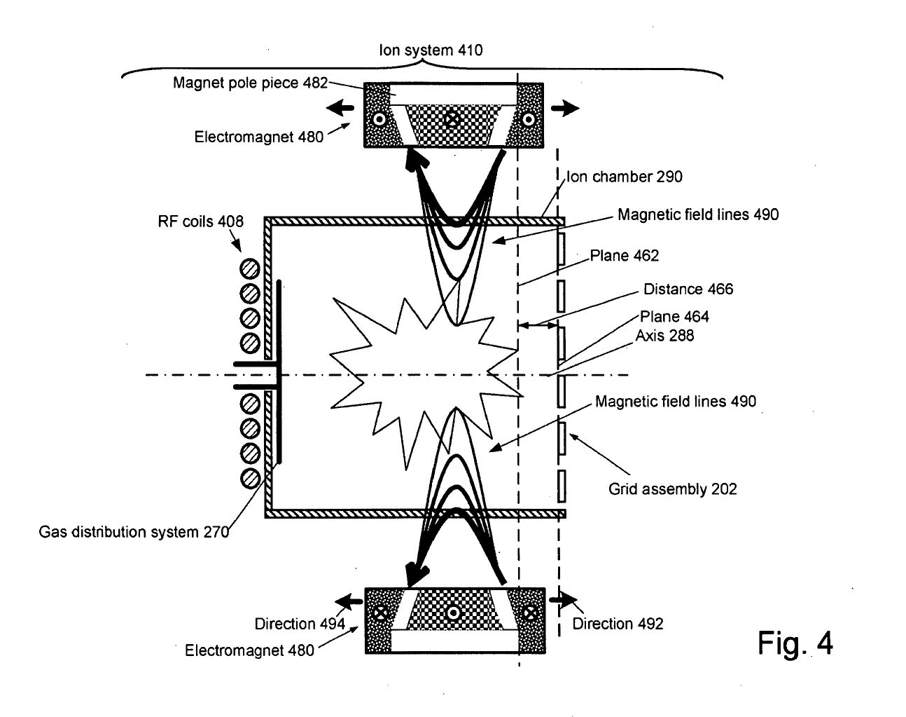

FIG. 4 shows a schematic representation illustrating a cross-sectional view of an ion system 410 for use in an etching system in accordance with one or more embodiments of the present invention. Ion system 410 may include one or more of ion chamber 290, grid assembly 202, and gas distribution system 270 discussed with reference to the example of FIG. 2A.

Ion system 410 may also include a set of pancake-type radio frequency coils 408 (RF coils 408) which may surround the gas inlet of gas distribution system 270 and/or may be disposed at an end of ion chamber 290 that is opposite to grid assembly 202. RF coils 408 may excite the gas supplied by gas distribution system 270 to generate charged particles (or ions).

Ion system 410 may also include an electromagnet 480 surrounding at least a portion of ion chamber 290. In one or more embodiments, electromagnet 480 may include a soft iron core as well as a set of coils with solonoidal windings. As an example, the soft iron core may be made of 430 series stainless steel. The coils may force the soft iron core to produce a desirable magnetic field profile inside ion chamber 290. By changing the coil currents, the strength and/or the distribution of the magnetic field can be varied.

Electromagnet 480 may provide a circularly uniform, symmetric magnetic field inside ion chamber 290 with a significant radial gradient inside ion chamber 290; the magnetic field may be represented by magnetic field lines 490. As illustrated by magnetic field lines 490, the circularly uniform magnetic field may be symmetric with respect to the central axis 288 of ion chamber 290, in contrast with asymmetric cusp magnetic field patterns that may be found in existing magnetic field applications. Cusp magnetic fields may reduce ion beam uniformity.

The density of magnetic field lines 490 may decrease from electromagnet 480 towards the central axis 288 of ion chamber 290. Accordingly, electromagnet 480 may be utilized for tuning the ion distribution in ion chamber 290, e.g., increasing ion density towards the cylindrical wall of ion chamber 290, thereby optimizing the etch uniformity when utilizing the etching system. The amount and/or distribution of electric current applied to electromagnet 480 may be controlled to control magnetic field lines 490, thereby further tuning the ion distribution. Electromagnet 480 may also be moved in at least one of direction 492 and direction 494 with respect to grid member 202 to providing further tuning.

In one or more embodiments, electromagnet 480 may be disposed near grid assembly 202. For example, distance 466 between plane 462 of a magnet pole piece 482 of electromagnet 480 and plane 464 of grid assembly 202 may be no more than the mean free path of the gas in ion chamber 290. Plane 462 may represent an imaginary plane that is perpendicular to central axis 288 and contains surface(s) of magnet pole piece 482 of electromagnet 480 that are closest to grid assembly 202. Plane 464 may represent an imaginary plane that is perpendicular to central axis 288 and contains surface(s) of grid assembly 202 that are closest to electromagnet 480. Accordingly, electromagnet 480 may be utilized in tuning the ion distribution in at least an etching process that may require relatively high ion-beam current/flux. In addition or alternative to electromagnet 480, gas distribution system 270 and associated control mechanisms may be utilized in tuning the ion distribution in at least an etching process that may require relatively low ion-beam current/flux. In one or more embodiments, both magnet 380 and gas distribution system 270 may be utilized in an etching process that may require intermediate ion-beam current/flux. Advantageously, comprehensive controllability for optimizing the etch rate may be provided.

In one or more embodiments, in addition to electromagnet 480, one or more additional magnets may be provided around different portions of ion chamber 290 for providing additional control of the ion distribution in ion chamber 290.

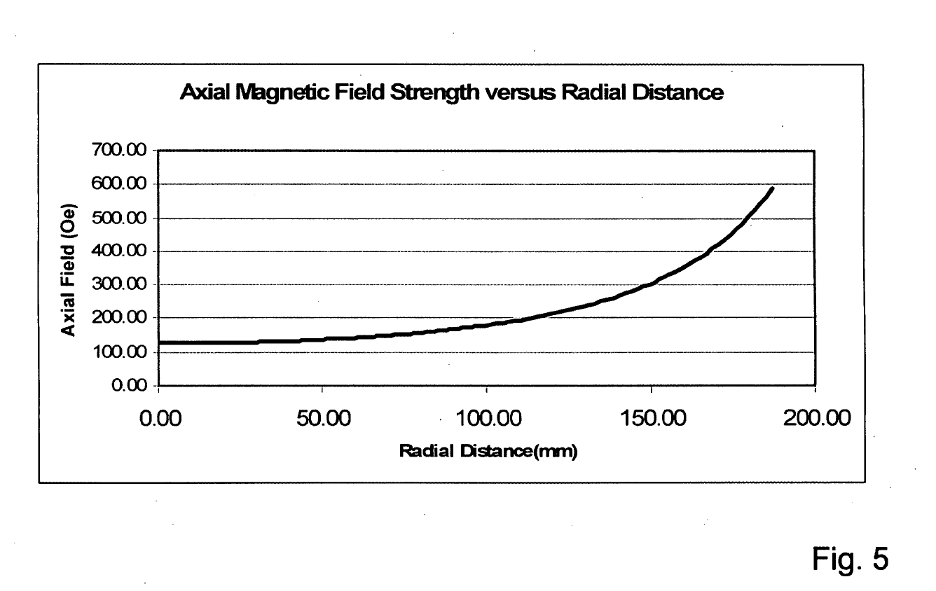

FIG. 5 shows a schematic chart illustrating example magnetic field strength values corresponding to different radial positions in an ion chamber (such as ion chamber 290 illustrated in the examples of FIGS. 2A, 3, and 4) for use in an etching system (such as etching system 200 illustrated in the examples of FIG. 2A) in accordance with one or more embodiments of the present invention. With a magnetic device (such as permanent magnet 380 illustrated in the example of FIG. 3 or electromagnet 480 illustrated in the example of FIG. 4) being implemented, as illustrated in the example of FIG. 5, the axial magnetic field strength may vary from about 120 Oe at central axis 288 of ion chamber 290 (illustrated in the example of FIG. 3 or FIG. 4) to about 600 Oe at the periphery (or cylindrical wall) of ion chamber 290. Advantageously, ion distribution may be optimized, and ion beam uniformity may be optimized without the need of varying grid hole sizes of grid assembly 202. Alternatively, these embodiments may be deployed to keep the grid hole variation to a minimum such that the best ion beam uniformity is obtained.

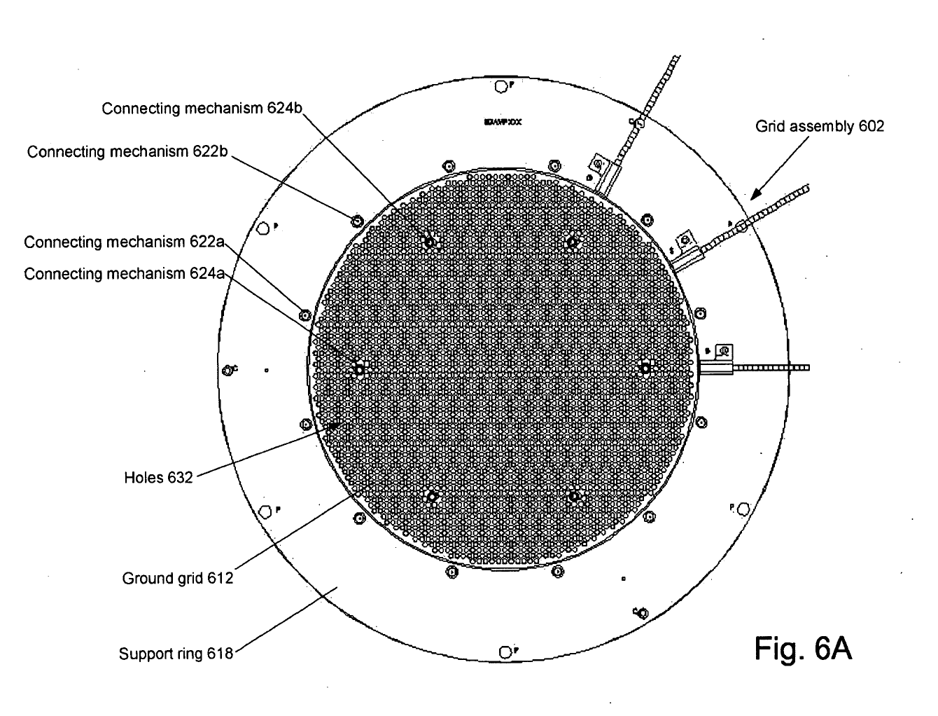

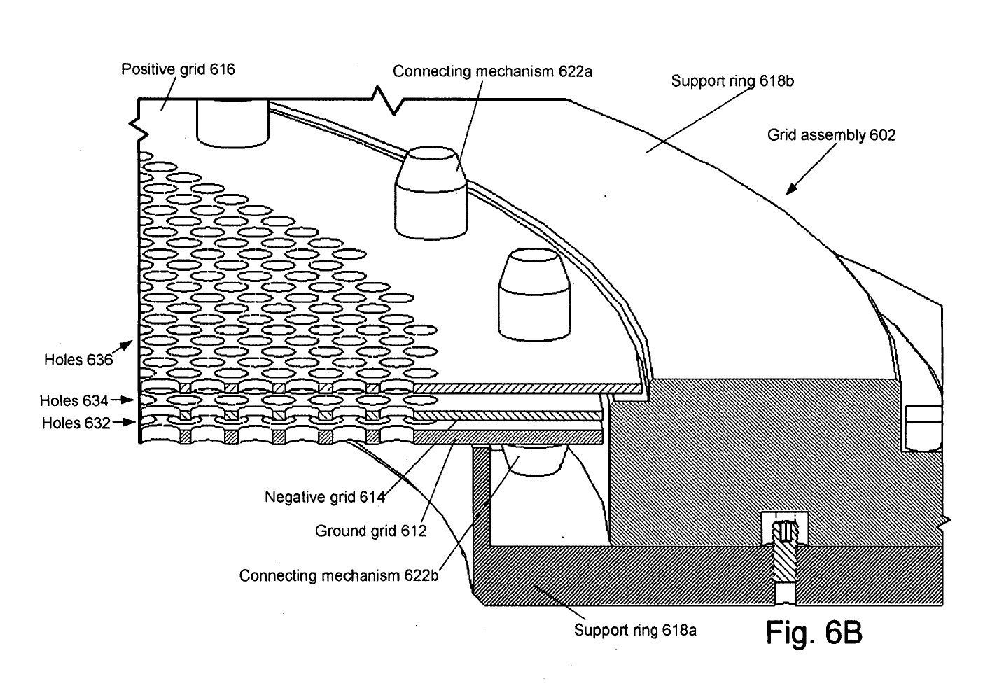

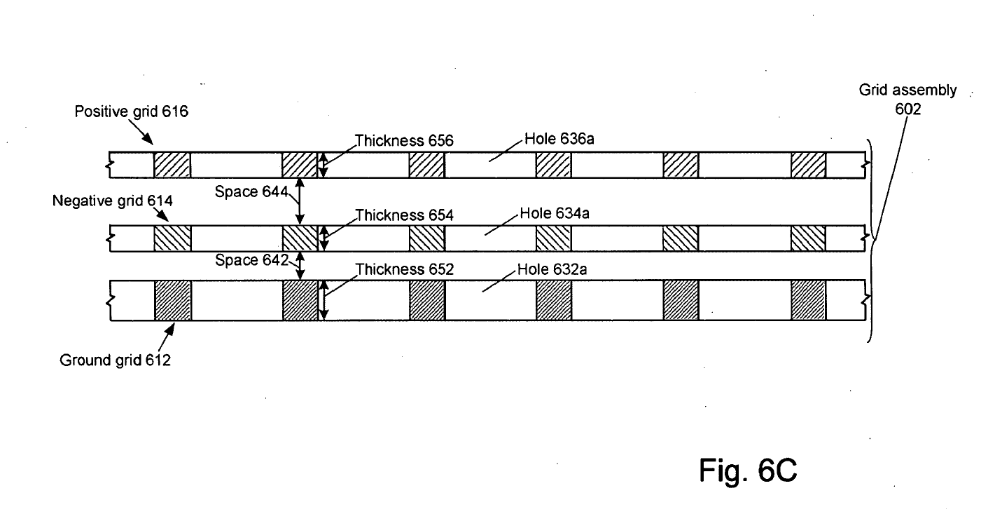

FIG. 6A shows a schematic representation illustrating a front view (as seen from a wafer) of a grid assembly 602 for use in an etching system in accordance with one or more embodiments of the present invention. For example, grid assembly 602 may be employed in place of grid assembly 202 in etching system 200 illustrated in the example of FIG. 2A. In this front view, a negative grid member and a positive grid member are hidden behind a ground grid member 612. In one or more embodiments, with the use of a multi-zone gas supply mechanism and/or a magnetic device, etch uniformity may be optimized with only minimal variation in grid hole variations.

Grid assembly 602 may also include a support ring 618. Support ring 618 may be made of stainless steel and may provide structural support for the grid members.

Grid assembly 602 may also include a set of connecting mechanisms, such as peripheral connecting mechanisms 622a-622b and inner connecting mechanisms 624a-624b. Support ring 618, ground grid member 612, the negative grid member, and the positive grid member may be coupled with one another through one or more of the connecting mechanisms.

The connecting mechanisms may provide structural rigidity and robustness for grid assembly 602. However, stress exerted on ground grid member 612, such as stress caused by deposition of waste material etched away from the wafer, and resulted structural distortion might be substantially transmitted through the connecting mechanisms to the negative grid member and the positive grid member if ground grid member 612 were not properly strengthened. Embodiments of the invention may strengthen ground grid member 612 by providing a sufficient thickness for ground grid member 612, as further discussed with reference to the examples of FIGS. 6B-6C.

FIG. 6B shows a schematic representation illustrating a cut-away view of grid assembly 602 illustrated in the example of FIG. 6A in accordance with one or more embodiments of the present invention. As illustrated in the example of FIG. 6B, ground grid member 612, negative grid member 614, and positive grid member 616 may be coupled by, for example, at least connecting mechanisms 622a-622b. Connecting mechanisms 622a-622b may provide electrical insulation between the grid members. At the same time, stress experience by any of the grid members might be transmitted through the connecting mechanisms if the grid members do not have sufficient strength.

Ground grid member 612 may be coupled with support ring 618a by, for example, at least connecting member 622b, for receiving structural support. Support ring 618a and support ring 618b may represent two interconnected members of support ring 618 illustrated in the example of FIG. 6A.

One or more of the connecting mechanisms, such as connecting mechanism 622b, may determine the size of the space between ground grid member 612 and negative grid member 614 and/or the size of the space between negative grid member 614 and positive grid member 616. The sizes of the spaces may be optimized to achieve desirable ion beam characteristics, thereby obtaining desirable etch uniformity and/or desirable etch rate, as further discussed with reference to FIG. 6C.

FIG. 6C shows a schematic representation illustrating a partial cross-sectional view of grid assembly 602 illustrated in the example of FIG. 6A in accordance with one or more embodiments of the present invention. As illustrated in the example of FIG. 6C, a first space 642 exists between ground grid member 612 and negative grid member 614, and a second space 644 exists between negative grid member 614 and positive grid member 616. First space 642 (or the size thereof) and/or second space 644 (or the size thereof) may be determined by one or more of the connecting mechanisms discussed above with reference to the examples of FIGS. 6A-6B.

In one or more embodiments, ion beam current through a grid hole (such as hole 636a) may be inversely proportional to the square of the distance between the negative grid member 614 and positive grid member 616. For achieving desirable etch uniformity, second space 644 may be made relatively large such that small variations in second space 644, for example, caused by warping of a grid member and/or deposition of sputtered waste material, may not cause significant ion beam current variation. As an example, second space 644 (or the width/size thereof) may be at least 0.055 inch, such as 0.07 inch. At the same time, an upper limit of second space 644 may be provided to avoid compromising the etch rate.

Additionally or alternatively, first space 642 may be configured relatively small such that a sufficiently good beam collimation. At the same time, first space 642 may be made large enough such that the ion beam intercept by the grid is kept small enough. As an example, first space 642 (or the width/size thereof) may be at least 0.035 inch and at most 0.055 inch, such as 0.045 inch. The relatively small first space 642 may also help maintain the structural robustness/rigidity of grid assembly 602.

Ground grid member 612, which faces the wafer during the etching, may be subjected to more sputtered waste material than the other two grid members. To resist the negative effects of the sputtered waste material, ground grid member 612 may be made thicker than one or more of the other two grid members. In other words, thickness 652 of ground grid member 662 may be larger than one or more of thickness 654 of negative grid member 614 and thickness 656 of positive grid member 616. The thicker ground grid member 612 may strengthen the structural robustness/rigidity of grid assembly 602 against potential warping, thereby advantageously helping maintain ion beam uniformity for achieving a satisfactory fabrication yield. The thicker ground grid member 612 may also lengthen the life of grid assembly 602.

Being at least partially shielded by ground grid assembly 612 against the sputtered waste material, negative grid member 614 and positive grid member 616 may be made relatively thin (compared with ground grid member 612). Being thinner, negative grid member 614 and positive grid member 616 may avoid releasing too much material that may contaminate the wafer when the grid members are subjected to grid-hole etching by ions provided from, for example, ion chamber 290 illustrated in the example of FIG. 2A. The thinner negative grid member 614 and positive grid member 616 may also help preserve sufficient sizes of second space 644 and first space 642, for maintaining the etch uniformity.

As can be appreciated from the foregoing, embodiments of the present invention may enable adjustments and optimization of ion distribution through the inventive features and inventive use of one or more of gas flow control, magnetic field control, etc. Embodiments of the present invention may provide more controllability over the prior art in optimizing ion distribution in both high-pressure regimes and low-pressure regimes in an ion system, for satisfying various etching processes that may require various ion-beam-current levels. Advantageously, etch uniformity may be more easily and practically achieved and maintained with embodiments of the invention.

Embodiments of the invention may also achieve desirable etch uniformity by keeping the variations in grid hole sizes to a minimum. Advantageously, costs associated with grid assemblies may be reduced. In addition, compared with etch uniformity provided by prior-art techniques, the etch uniformity provided by embodiments of the invention may be less sensitive to changes to the grid assembly caused by, for example, deposition of etched waste material that is sputtered on the grid assembly.

Embodiments of the present invention may also strengthen structural robustness and/or rigidity of a grid assembly without compromising the space between the negative grid member and the positive grid member of the grid assembly. As a result, satisfactory grid assembly durability, etch stability, and etch uniformity may be provided. Advantageously, the costs associated with performing etching may be substantially reduced, and the yield in fabricating devices may be improved.

While this invention has been described in terms of several embodiments, there are alterations, permutations, and equivalents, which fall within the scope of this invention. It should also be noted that there are many alternative ways of implementing the methods and apparatuses of the present invention. Furthermore, embodiments of the present invention may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

1. An ion system for use in an etching system for etching at least a wafer using a gas, the ion system comprising:
an ion chamber for containing charged particles generated from the gas, comprising a flat first end, a second end opposite the first end, a central axis passing from the first end to the second end, and a side parallel to the central axis;
a magnetic device having an inner diameter, said magnetic device surrounding at least a portion of the ion chamber adjacent the side of the ion chamber, the magnetic device being configured to affect distribution of the charged particles in the ion chamber;
a grid assembly disposed between the ion chamber and the wafer when the wafer is etched, the charged particles being provided through the grid assembly to etch the wafer when the wafer is etched;
an electric current control device for controlling at least one of an amount and distribution of electric current supplied to the magnetic device, wherein the magnetic device is an electromagnetic device;
a movement mechanism coupled with the magnetic device, the movement mechanism being configured to actuate the magnetic device to move along the side of the ion chamber with respect to the grid assembly; and
a set of radio frequency coils having an outer diameter, the outer diameter of the set of radio frequency coils being smaller than the inner diameter of the magnetic device, the set of radio frequency coils surrounding at least a portion of the ion chamber, the set of radio frequency coils being configured to generate the charged particles, and the magnetic device adapted to provide circularly uniform magnetic field lines inside the ion chamber.

2. (canceled)

3. (canceled)

4. (canceled)

5. (canceled)

6. (canceled)

7. (canceled)

8. (canceled)

9. (canceled)

10. (canceled)

11. (canceled)

12. The ion system of claim 1, further comprising:
a first grid member disposed between the second end of the ion chamber and a wafer support mechanism, the first grid member including a first set of holes, the first grid member being configured to be electrically grounded when the etching system is used in etching the wafer;
a second grid member disposed between the second end of the ion chamber and the wafer support mechanism, the second grid member including a second set of holes, the second grid member being configured to be electrically negative relative to the first grid member when the etching system is used in etching the wafer, the second grid member defining a first space between the first and second grid members, the first space being sized for maintaining beam divergence while etching the wafer; and
a third grid member disposed between the second end of the ion chamber and the wafer support mechanism, the third grid member including a third set of holes, the third grid member being configured to be electrically positive relative to the first grid member when the etching system is used in etching the wafer, the second grid member being disposed between the first grid member and the third grid member, the third grid member defining a second space between the second and third grid member, the second space being larger than the first space.

13. (canceled)

14. (canceled)

15. (canceled)

16. (canceled)

17. (canceled)

18. (canceled)

19. (canceled)

20. (canceled)

21. The ion system of claim 1, further comprising a gas distribution system disposed inside the ion chamber near the first end, the gas distribution system formed with a first group of gas channels having a first opening size positioned in a circular arc and a second set of gas channels having a second opening size formed in another circular arc between the first group of gas channels and an outer peripheral edge of the gas distribution system, said first opening size being smaller than said second opening size.

22. The ion system of claim 1, further comprising an adjustable wafer support mechanism, said adjustable wafer support mechanism being adjustable for position and orientation of the wafer.

23. An ion system for use in an etching system for etching at least a wafer using a gas, the ion system comprising:
an ion chamber for containing charged particles generated from the gas, comprising a flat first end, a second end opposite the first end, a central axis passing from the first end to the second end, and a side parallel to the central axis;
an adjustable wafer support mechanism, said adjustable wafer support mechanism being adjustable for position and orientation of the wafer;
a magnetic device having an inner diameter, said magnetic device surrounding at least a portion of the ion chamber adjacent the side of the ion chamber, the magnetic device being configured to affect distribution of the charged particles in the ion chamber;
a first grid member disposed between the second end of the ion chamber and a wafer support mechanism, the first grid member including a first set of holes, the first grid member being configured to be electrically grounded when the etching system is used in etching the wafer;
a second grid member disposed between the second end of the ion chamber and the wafer support mechanism, the second grid member including a second set of holes, the second grid member being configured to be electrically negative relative to the first grid member when the etching system is used in etching the wafer, the second grid member defining a first space between the first and second grid members, the first space being sized for maintaining beam divergence while etching the wafer;
a third grid member disposed between the second end of the ion chamber and the wafer support mechanism, the third grid member including a third set of holes, the third grid member being configured to be electrically positive relative to the first grid member when the etching system is used in etching the wafer, the second grid member being disposed between the first grid member and the third grid member, the third grid member defining a second space between the second and third grid member, the second space being larger than the first space an electric current control device for controlling at least one of an amount and distribution of electric current supplied to the magnetic device, wherein the magnetic device is an electromagnetic device;
a gas distribution system disposed inside the ion chamber near the first end, the gas distribution system formed with a first group of gas channels having a first opening size positioned in a circular arc and a second set of gas channels having a second opening size formed in another circular arc between the first group of gas channels and an outer peripheral edge of the gas distribution system, said first opening size being smaller than said second opening size;
a movement mechanism coupled with the magnetic device, the movement mechanism being configured to actuate the magnetic device to move along the side of the ion chamber with respect to the grid assembly; and
a set of radio frequency coils having an outer diameter, the outer diameter of the set of radio frequency coils being smaller than the inner diameter of the magnetic device, the set of radio frequency coils surrounding at least a portion of the ion chamber, the set of radio frequency coils being configured to generate the charged particles, and the magnetic device adapted to provide circularly uniform magnetic field lines inside the ion chamber.
